(19) United States
(12) Patent Application Publication
(10) Pub. No.: US 2006/0254639 A1
(43) Pub. Date: Nov. 16, 2006

(54) Photoelectric conversion element, photoelectric conversion device and method for producing photoelectric conversion element

(75) Inventor: Yoshio Idota, Minami-Ashigara-shi (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 11/359,382

(22) Filed: Feb. 23, 2006

(30) Foreign Application Priority Data
Feb. 25, 2005 (JP) P.2005-050944

(51) Int. Cl. H01L 31/00

(52) U.S. Cl. 136/263

(57) ABSTRACT

A photoelectric conversion element comprising: a layer containing an organic compound having a crystallization temperature of from 30 to 200° C.; an intermediate layer containing a compound having a crystallization temperature higher by from 20 to 100° C. than the crystallization temperature of the organic compound and a deposition temperature higher by from 30 to 200° C. than a deposition temperature of the organic compound; and a functional layer containing a compound having a crystallization temperature lower by from 20 to 100 ° C. than the crystallization temperature of the organic compound and a deposition temperature higher by from 50 to 300° C. than a deposition temperature of the organic compound, provided in this order.

### FIELD OF THE INVENTION

This invention relates to a multilayer color light-receiving device or a color light-emitting device using an organic compound and a method of fabricating the same. It further relates to a method of regulating a dark current and inhibiting the formation of uneven image spots.

### BACKGROUND OF THE INVENTION

It is well known that the main component of a functional layer unevenly crystallize in the course of producing a photoelectric conversion device. For example, JP-A-60-201658 discloses a method of preventing crystallization by providing a transparent electrode (a surface-smoothened layer) made of, for example, ITO below an amorphous silicone layer for photoelectric conversion. Further, JP-A-6-5223 proposes to insert a layer for preventing crystallization such as a silicon nitride layer between a first and second amorphous selenium layers for photoelectric conversion, and JP-A-10-228982 discloses a method of preventing the crystallization of an organic dye amorphous layer of an organic light-emitting device by adding a compound having a structure similar to the dye.

In the case where two layers of specific organic compounds are adjacently located, however, further improvement should be made.

### SUMMARY OF THE INVENTION

A problem that the invention is to solve is to provide a method whereby a compound which is liable to crystallize can be prevented from crystallization in the case of forming a layer comprising a compound having a high deposition temperature on a layer of the compound being liable to crystallize.

The problem as described above can be solved by the following means.

(1) A photoelectric conversion element wherein, between a layer which contains an organic compound having a crystallization temperature of 30° C. or higher but not higher than 200° C. and a functional layer which contains a compound having a crystallization temperature lower by 20° C. or more but not more than 100° C. than the crystallization temperature of the organic compound and a deposition temperature higher by 50° C. or more but not more than 300° C. than the deposition temperature of the organic compound, a layer (an intermediate layer) which contains a compound having a crystallization temperature higher by 20° C. or more but not more than 100° C. than the crystallization temperature of the organic compound and a deposition temperature higher by 30° C. or more but not more than 200° C. than the deposition temperature of the organic compound is provided.

(2) A photoelectric conversion element as described in the above (1) wherein the layer containing the organic compound is a charge blocking layer.

(3) A photoelectric conversion element as described in the above (1) or (2) wherein the functional layer is a photoelectrical conversion layer.

(4) A photoelectric conversion element as described in the above (1) wherein the main component of the intermediate layer has a work function falling within a reasonable scope in the energy diagrams of the compounds adjacent thereto.

(5) A photoelectric conversion element as described in any one of the above (1) to (4) wherein the main component of the intermediate layer is aluminum quinoline.

(6) A photoelectric conversion device having a photoelectric conversion element as described above.

(7) A method of producing a photoelectric conversion element comprising successively forming by the vacuum vapor deposition method at 10⁻⁶ Pa or below a layer which contains an organic compound having a crystallization temperature of 30° C. or higher but not higher than 200° C., a layer which contains a compound having a crystallization temperature higher by 20° C. or more but not more than 100° C. than the crystallization temperature of the organic compound and a deposition temperature higher by 30° C. or more but not more than 200° C. than the deposition temperature of the organic compound, and a functional layer which contains a compound having a crystallization temperature lower by 20° C. or more but not more than 100° C. than the crystallization temperature of the organic compound and a deposition temperature higher by 50° C. or more but not more than 300° C. than the deposition temperature of the organic compound.

(8) A light-emitting device wherein, between a layer which contains an organic compound having a crystallization temperature of 30° C. or higher but not higher than 200° C. and a functional layer which contains a compound having a crystallization temperature lower by 20° C. or more but not more than 100° C. than the crystallization temperature of the organic compound and a deposition temperature higher by 50° C. or more but not more than 300° C. than the deposition temperature of the organic compound, a layer (an intermediate layer) which contains a compound having a crystallization temperature higher by 20° C. or more but not more than 100° C. than the crystallization temperature of the organic compound and a deposition temperature higher by 30° C. or more but not more than 200° C. than the deposition temperature of the organic compound is provided.

(9) A light-emitting device as described in the above (8) wherein the layer containing the organic compound is a charge blocking layer.

(10) A light-emitting device as described in the above (8) or (9) wherein the functional layer is a photoelectrical conversion layer.

(11) A light-emitting device as described in the above (8) wherein the main component of the intermediate layer has a work function falling within a reasonable scope in the energy diagrams of the compounds adjacent thereto.

(12) A light-emitting device as described in any one of the above (8) to (12) wherein the main component of the intermediate layer is aluminum quinoline.

(13) A method of producing a light-emitting device comprising successively forming by the vacuum vapor deposition method at 10⁻⁶ Pa or below a layer which contains an organic compound having a crystallization temperature of 30° C. or higher but not higher than 200° C., a layer which contains a compound having a crystallization temperature higher by 20° C. or more but not more than 100° C. than the crystallization temperature of the organic compound and a deposition temperature higher by 30° C. or more but not more than 200° C. than the deposition temperature of the organic compound, and a functional layer which contains a compound having a crystallization temperature lower by 20° C. or more but not more than 100° C. than the crystallization temperature of the organic compound and a deposition temperature higher by 50° C. or more but not more than 300° C. than the deposition temperature of the organic compound.

In the case of forming a layer of a compound having a high deposition temperature as an upper layer of a layer being liable to crystallize (in the process), the crystallization of the main component of the layer being liable to crystallize can be prevented by forming a layer (an intermediate layer) being relatively hardly liable to crystallize between the above-described layers. As a result, a dark current can be lowered and the formation of white spots (in the case of a light-receiving device) or black spots (in the case of a light-emitting device) can be inhibited.

### BRIEF DESCRIPTION OF THE DRAWINGS

FIG. 1 shows a preferred embodiment of the photoelectric conversion device according to the invention.

FIG. 2 shows another preferred embodiment of the photoelectric conversion device according to the invention.

### DESCRIPTION OF THE REFERENCE NUMERALS AND SIGNS

1 silicone substrate
2 first semiconductor area (p-type)
3 second semiconductor area (n-type)
4 third semiconductor area (p-type)
5, 9 transparent insulating element
6 pixel electrode (transparent)
7 photoelectric conversion element
7-1 hole blocking layer
7-2 layer for preventing uneven crystallization
7-3 G photoelectric conversion layer
8 counter electrode (transparent)
10 G pixel signal-detecting part
11 B pixel signal-detecting part
12 R pixel signal-detecting part
13 first photodiode
14 second photodiode
101 antireflective element
102 infrared-cutting dielectric multilayer element
103, 104 protective element
105 counter electrode
106 electron blocking layer
170 p layer
108 n layer
109 layer for preventing uneven crystallization
110 hole blocking layer
111, 112 layer containing metal wiring
113 monocrystalline silicone base
114 transparent pixel electrode
115 plug
116 pad
117 photo blocking element
118 connection electrode
119 metal wiring
120 counter electrode pad
121 n layer
122 p layer
123 n layer
124 p layer
125 n layer
126 transistor
127 signal-reading pad

### DETAILED DESCRIPTION OF THE INVENTION

A constitutional characteristic of the invention resides in, between a layer which contains as the main component (preferably 50% by weight or more of, more preferably 70% by weight or more of) an organic compound having a crystallization temperature of 30° C. or higher but not higher than 200° C. and a functional layer which contains as the main component (preferably 50% by weight or more of, more preferably 70% by weight or more of) a compound having a crystallization temperature lower by 20° C. or more but not more than 100° C. than the crystallization temperature of the organic compound and a deposition temperature higher by 50° C. or more but not more than 300° C. than the deposition temperature of the organic compound, a layer (an intermediate layer) which contains as the main component (preferably 50% by weight or more of, more preferably 70% by weight or more of) a compound having a crystallization temperature higher by 20° C. or more but not more than 100° C. than the crystallization temperature of the organic compound and a deposition temperature higher by 30° C. or more but not more than 200° C. than the deposition temperature of the organic compound is formed. Although the deposition temperature of the organic compound is heavily dependent on degree of vacuum, it is preferably from 100 to 500° C., and more preferably from 200 to 400° C.

The term “deposition temperature” as used herein is defined as the temperature at which deposition can be carried out at a degree of vacuum of 2×10⁻⁴ Pa at a speed of 0.05 nm/sec. The term “crystallization temperature” is defined as the temperature at which a solid compound in the amorphous state having been deposited on a target at room temperature starts to crystallize while rising temperature at a rate of 2° C./min.

A less thickness of the intermediate layer is preferred. That is, it is preferable that the thickness of the intermediate layer is from such a level that a layer can be substantially formed to 1 μm, still preferably not more than 500 nm (preferably 1 nm or more). The compound to be used as the main component of the intermediate layer is a compound which has a crystallization temperature higher by 20° C. or more but not more than 100° C. and a deposition temperature higher by 30° C. or more but not more than 200° C., each compared with the organic compound in the layer (the lower layer) which contains as the main component (preferably 50% by weight or more of, more preferably 70% by weight or more of) an organic compound having a crystallization temperature of 30° C. or higher but not higher than 200° C. It is particularly preferable that the compound to be used as the main component of the intermediate layer has a crystallization temperature higher by 30° C. or more but not more than 80° C. and a deposition temperature higher by 40° C. or more but not more than 180° C. It is also preferable that the compound has a work function falling within a reasonable scope in the energy diagrams of the compounds adjacent thereto. The “reasonable scope in the energy diagrams” means that exothermic transfer of electron or hole is possible, or gap of the work function is within 0.3 eV even if it is endothermic. That is to say, it is preferable that its work function is located at such a position as substantially causing no trouble in the energy diagrams of the lower and upper layers. It is still preferable that the work function is located at around the middle point thereof. It is also preferable that the compound has a charge migration ability. As specific examples of the compound, an organic compound is preferred, an organic compound containing a metal ion is more preferred and aluminum quinoline is particularly preferred.

In the invention, it is preferable that the main components of the layers, between which the intermediate layer is sandwiched, have photoelectric conversion (light-receiving), electroluminescent conversion (light-emitting), charge transfer or charge blocking functions.

It is preferable that the layer which contains as the main component (preferably 50% by weight or more of, more preferably 70% by weight or more of) an organic compound having a crystallization temperature of 30° C. or higher but not higher than 200° C. has a charge transfer or charge blocking function. It is further preferable that the layer is a charge blocking layer.

It is preferable that the functional layer which contains as the main component (preferably 50% by weight or more of, more preferably 70% by weight or more of) a compound having a crystallization temperature lower by 20° C. or more but not more than 100° C. than the crystallization temperature of the organic compound and a deposition temperature higher by 50° C. or more but not more than 300° C. than the deposition temperature of the organic compound is a photoelectric conversion (light-receiving) layer or a electroluminescent (light-emitting) layer.

Although the thickness of each of these layers may be at such a level as allowing the achievement of the definite purpose, it is preferably 10 nm or more but not more than 2 μm, still preferably 50 nm or more but not more than 500 nm.

The compounds layers (including the three layers as discussed above) may be formed by a dry element-forming method or a wet element-forming method. Specific examples of the dry element-forming method include physical vapor phase epitaxy methods such as the vacuum vapor deposition method, the sputtering method, the ion plating method and the MBE method, and CVD methods such as the plasma polymerization method. Examples of the wet element-forming method include the casting method, the spin coating method, the dipping method and the LB method. In the case of using a polymer compound as at least one of a p-type semiconductor (compound) and an n-type semiconductor (compound), it is favorable to form the layer by a wet element-forming method which can be easily carried out. When a dry element-forming method such as the vapor deposition method is employed, it is highly difficult to employ a polymer compound because of a fear of decomposition. In such a case, use may be preferably made of a corresponding oligomer as a substitute for the polymer. In the case of using a low-molecular weight compound in the invention, use is preferably made of a dry element-forming method and the vacuum vapor deposition method is particularly preferred. Fundamental parameters in the vacuum vapor deposition method include a method of heating a compound (e.g., the resistance heating method, the electron beam heating/deposition method or the like), the shape of the deposition source such as a crucible or a boat, the degree of vacuum, the deposition temperature, the substrate temperature, the deposition speed and so on. To achieve uniform deposition, it is favorable to carry out the deposition while rotating the substrate. A higher degree of vacuum is preferred. The vacuum vapor deposition is performed at a degree of vacuum of 10⁻² Pa or lower, preferably 10⁻⁴ Pa or lower and particularly preferably 10⁻⁶ Pa or lower. It is preferable to carry out all of the vapor deposition steps in vacuo. Fundamentally, the subject compound should be prevented from direct contact with the external oxygen or moisture. The vacuum vapor deposition conditions as described above should be strictly controlled, since the crystallinity, amorphous properties, density and denseness of the organic layer are affected thereby. It is preferable to PI or PID control the deposition speed with the use of a thickness monitor such as a crystal oscillator or an interferometer. In the case of depositing two or more compounds at the same time, use may be preferably made of the co-deposition method, the flash deposition method or the like.

(Photoelectric Conversion Device)

Next, the photoelectric conversion device of the invention will be illustrated.

The photoelectric conversion device of the invention comprises an electromagnetic wave absorption/photoelectric conversion part and a charge storage/transfer/reading part for the charge generated by the photoelectric conversion.

The electromagnetic wave absorption/photoelectric conversion part in the invention has a laminated structure composed of at least two layers whereby at least blue light, green light and red light can be absorbed and photoelectrically converted. The blue light absorption layer (B) can absorb light with wavelength of at least 400 nm to 500 nm and the absorption index of the peak wavelength in this region is preferably 50% or more. The green light absorption layer (G) can absorb light with wavelength of at least 500 nm to 600 nm and the absorption index of the peak wavelength in this region is preferably 50% or more. The red light absorption layer (R) can absorb light with wavelength of at least 600 nm to 700 nm and the absorption index of the peak wavelength in this region is preferably 50% or more. These layers may be formed in any order. In a laminated structure composed of three layers, use may be made of the orders of, from the upper side, BGR, BRG, GBR, GRB, RBG and RGB. It is preferable that G is provided as the uppermost layer. In a laminated structure composed of two layers wherein an R layer is provided as the upper layer, BG layers are provided on a single plane to form the lower layer. In the case where a B layer is provided as the upper layer, GR layers are provided on a single plane to form the lower layer. In the case where a G layer is provided as the upper layer, BR layers are provided on a single plane to form the lower layer. It is preferable that the G layer is provided as the upper layer while the BR layers are provided as the lower layer. In such a case where two light absorption layers are provided on a single plane as the lower layer, it is preferable to form a filter layer (for example, in a mosaic structure) for color separation on the upper layer or between the upper and lower layers. It is also possible to form three or more light absorption layers as additional layers or on the same plane.

The charge storage/transfer/reading part is provided under the electromagnetic wave absorption/photoelectric conversion part. It is preferred that the electromagnetic wave absorption/photoelectric conversion part in the lower layer also serves as the charge storage/transfer/reading part.

In the invention, it is preferable that the electromagnetic wave absorption/photoelectric conversion part comprises an organic layer, an inorganic layer or a combination of an organic layer with an inorganic layer. Organic layers may be B/G/R layers. Alternatively, inorganic layers may be B/G/R layers. A combination of an organic layer with an inorganic layer is preferred. Such combined use is disclosed in JP-A-1-282875. Fundamentally, one or two inorganic layers are formed in the case of forming an organic layer, and one inorganic layer is formed in the case of forming two organic layers. In the case of forming an organic layer and an inorganic layer, the inorganic layer forms electromagnetic wave absorption/photoelectric conversion parts in two or more colors on a single plane. It is preferable that the upper layer is an organic layer serving as the G layer while the lower layers are inorganic layers comprising the B layer and the R layer in this order from the upper side. It is also possible in some cases to form additional layer(s) as the fourth layer or higher or on the same plane. In the case where organic layers are B/G/R layers, it is preferable to form the charge storage/transfer/reading part under these layers. In the case of using an inorganic layer as the electromagnetic wave absorption/photoelectric conversion part, it is preferable that the inorganic layer also serves as the charge storage/transfer/reading part.

(Organic Layer)

Now, the organic layer in the invention will be illustrated. In the invention, an electromagnetic wave absorption/photoelectric conversion part made of an organic layer comprises the organic layer located between a pair of electrodes. The organic layer is made up of an electromagnetic wave absorption part, an electron transportation part, a photoelectric conversion part, a hole transportation part, an electron blocking part, a hole blocking part, a crystallization prevention part, electrodes, an interlayer contact improvement part and so on which are piled up or mixed together. It is preferable that the organic layer contains an organic p-type compound or an organic n-type compound. The organic p-type semiconductor (compound), which is a donor type organic semiconductor (compound), is typified mainly by a hole-transporting organic compound, i.e., an organic compound being liable to donate electron. To speak in greater detail, it means an organic compound having a lower ionization potential in the case of using two organic materials in contact with each other. That is to say, any compound capable of donating electron can be used as the donor type organic compound. For example, use can be made of triarylamine compounds, benzidine compounds, pyrazoline compounds, styrylamine compounds, hydrazone compounds, triphenylmethane compounds, carbazole compounds, polysilane compounds, thiophene compounds, phthalocyanine compounds, cyanine compounds, merocyanine compounds, oxonole compounds, polyamine compounds, indole compounds, pyrrole compounds, pyrazole compounds, polyarylene compounds, fused ring aromatic carbon ring compounds (naphthalene derivatives, anthracene derivatives, phenanthrene derivatives, tetracene derivatives, pyrene derivatives, perylene derivatives and fluoranthene derivatives), metal complexes having nitrogen-containing heterocyclic compounds as a ligand and so on. However, the invention is not restricted to these compounds and use may be made, as the donor type organic semiconductor, of any organic compound which has a lower ionization potential than the organic compound employed as the n-type (acceptor type) compound as discussed above.

The organic n-type semiconductor (compound), which is an acceptor type organic semiconductor (compound), is typified mainly by an electron-transporting compound, i.e., an organic compound being liable to accept electron. To speak in greater detail, it means an organic compound having a higher affinity in the case of using two organic materials in contact with each other. That is to say, any compound capable of accepting electron can be used as the acceptor type organic compound. For example, use can be made of fused ring aromatic carbon ring compounds (naphthalene derivatives, anthracene derivatives, phenanthrene derivatives, tetracene derivatives, pyrene derivatives, perylene derivatives and fluoranthene derivatives), 5- to 7-membered heterocyclic compounds having a nitrogen atom, an oxygen atom or a sulfur atom (for example, pyridine, pyrazine, pyrimidine, pyridazine, triazine, quinoline, quinoxaline, quinazoline, phthalazine, cinnoline, isoquinoline, pteridine, acridine, phenazine, phenanthroline, tetrazole, pyrazole, imidazole, thiazole, oxazole, indazole, benzimidazole, benzotriazole, benzoxazole, benzothiazole, carbazole, purine, triazolopyridazine, triazolopyrimidine, tetrazaindene, oxadiazole, imidazopyridine, pyrralizine, pyrrolopyridine, thiadiazolopyridine, dibenzazepine and tribenzazepine), polyarylene compounds, fluorene compounds, cyclopentadiene compounds, silyl compounds, metal complexes having nitrogen-containing heterocyclic compounds as a ligand and so on. However, the invention is not restricted to these compounds and use may be made, as the acceptor type organic semiconductor, of any organic compound which has a higher affinity than the organic compound employed as the donor type organic compound as discussed above.

Although any compounds are usable as the p-type organic dye or the n-type organic dye, preferable examples thereof include cyanine dyes, styryl dyes, hemicyanine dyes, merocyanine dyes (including zeromethine merocyanine (simple merocyanine)), three-nuclear merocyanine dyes, four-nuclear merocyanine dyes, rhodacyanine dyes, complex cyanine dyes, complex merocyanine dyes, aro polar dyes, oxonole dyes, hemioxonole dyes, squarium dyes, croconium dyes, azamethine dyes, coumarine dyes, arylidene dyes, anthraquinone dyes, triphenylmethane dyes, azo dyes, azomethine dyes, spiro compounds, metallocene dyes, fluorenone dyes, flugide dyes, perylene dyes, phenazine dyes, phenothiazine dyes, quinone dyes, indigo dyes, diphenylmethane dyes, polyene dyes, acridine dyes, acridinone dyes, diphenylamine dyes, quinacridone dyes, quinophthalone dyes, phenoxazine dyes, phthaloperylene dyes, porphyrin dyes, chlorophyll dyes, phthalocyanine dyes, metal complex dyes, fused ring aromatic carbon ring compounds (naphthalene derivatives, anthracene derivatives, phenanthrene derivatives, tetracene derivatives, pyrene derivatives, perylene derivatives and fluoranthene derivatives) and so on.

Next, a metal complex compound will be illustrated. A metal complex compound is a metal complex which carries a ligand having at least one nitrogen atom, oxygen atom or sulfur atom and coordinating with a metal. Although the metal ion in such a metal complex is not particularly restricted, preferable examples thereof include beryllium ion, magnesium ion, aluminum ion, gallium ion, zinc ion, indium ion and tin ion, still preferably beryllium ion, aluminum ion, gallium ion or zinc ion, and still preferably aluminum ion or zinc ion. As the ligand contained in the above metal complex, various publicly known ligands may be cited. For example, use can be made of ligands reported in Photochemistry and Photophysics of Coordination Compounds, published by Springer-Verlag, H. Yersin (1987) and Yuki Kinzoku Kagaku-Kiso to Oyo, published by Shokabo, Akio Yamamoto (1982) and so on.

Preferable examples of the above ligand include nitrogen-containing heterocyclic ligands (preferably having from 1 to 30 carbon atoms, still preferably from 2 to 20 carbon atoms, and particularly preferably form 3 to 15 carbon atoms; including both of monodentate ligands and higher, bidentate ligands being preferred, e.g., pyridine ligands, bipyridyl ligands, quinolynol ligands, hydroxyphenylazole ligands such as hydroxyphenylbenzimidazole ligand, hydroxyphenylbenzoxazole ligand and hydroxyphenylimidazole ligand), alkoxy ligands (preferably having from 1 to 30 carbon atoms, still preferably from 1 to 20 carbon atoms and particularly preferably from 1 to 10 carbon atoms, such as methoxy, ethoxy, butoxy and 2-ethylhyxyloxy), aryloxy ligands (preferably having from 6 to 30 carbon atoms, still preferably from 6 to 20 carbon atoms and particularly preferably from 6 to 12 carbon atoms, such as phenyloxy, 1-naphthyloxy, 2-naphthyloxy, 2,4,6-trimethylphenyloxy and 4-biphenyloxy), heteroaryloxy ligands (preferably having from 1 to 30 carbon atoms, still preferably form 1 to 20 carbon atoms and particularly preferably from 1 to 12 carbon atoms, such as pyridyloxy, pyrazyloxy, pyrimidyloxy and quinolyloxy), alkylthio ligands (preferably having from 1 to 30 carbon atoms, still preferably from 1 to 20 carbon atoms and particularly preferably from 1 to 12 carbon atoms, such as methylthio and ethylthio), arylthio ligands (preferably having from 6 to 30 carbon atoms, still preferably from 6 to 20 carbon atoms and particularly preferably from 6 to 12 carbon atoms, such as phenylthio), heterocycle-substituted thio ligands (preferably having from 1 to 30 carbon atoms, still preferably from 1 to 20 carbon atoms and particularly preferably from 1 to 12 carbon atoms, such as pyridylthio, 2-benzimidazolylthio, 2-benzoxazolylthio and 2-benzthiazolylthio) and siloxy ligands (preferably having from 1 to 30 carbon atoms, still preferably from 3 to 25 carbon atoms and particularly preferably from 6 to 20 carbon atoms, such as triphenylsiloxy group, triethoxysiloxy group and triisopropylsiloxy group). Still preferable examples thereof include nitrogen-containing heterocyclic ligands, aryloxy ligands, heteroaryloxy groups and siloxy ligands, and nitrogen-containing heterocyclic ligands, aryloxy ligands and siloxy ligands are still preferable.

In the invention, it is preferable to contain a photoelectric conversion element (a photosensitive layer) which has a p-type semiconductor layer and an n-type semiconductor layer between a pair of electrodes and also has a bulk heterojunction layer containing the p-type semiconductor and the n-type semiconductor as an intermediate layer between these semiconductor layers. In this case, the shortage of the organic layer of having a short carrier diffusion length can be overcome owing to the bulk heterojunction structure in the organic layer and thus the photoelectric conversion efficiency can be elevated. The bulk heterojunction structure is described in detail in “Organic electronics-photonics materials and Device”, pages 333-335, supervised by Toshihiko Nagamura (CMC, September of 2003).

It is preferable in the invention to contain a photoelectric conversion element (a photosensitive layer which has two or more repeating structure units of a pn junction layer comprising a p-type semiconductor layer and an n-type semiconductor layer between a pair of electrodes (a tandem structure). It is still preferable to insert a thin layer made of an electrically conductive material between these repeating structure units. Although the number of the repeating structure units of the pn junction layers (the tandem structure) is not restricted, it preferably ranges from 2 to 50, still preferably from 2 to 30 and particularly preferably 2 or 10, from the viewpoint of achieving a high photoelectric conversion efficiency. As the electrically conductive material, silver or gold is preferable and silver is most desirable. The tandem structure is described in detail in Japanese Patent Application No. 2004-079930.

In a photoelectric conversion element having a p-type semiconductor layer and an n-type semiconductor layer between a pair of electrodes (preferably a mixture/dispersion (bulk heterojunction) layer), a photoelectric conversion element containing an organic compound having controlled orientation at least in one of the p-type semiconductor and the n-type semiconductor is preferable and a photoelectric conversion element containing organic compounds having (possibly) controlled orientation in both of the p-type semiconductor and the n-type semiconductor is still preferred. As the organic compound to be used in the organic layer of the photoelectric conversion element, it is preferable to employ one having a π-conjugated electron. It is favorable to use a compound having been oriented to give an angle of this π electron plane which is not perpendicular but as close to parallel as possible to the substrate (the electrode substrate). The angle to the substrate is preferably 0° or larger but not larger than 80°, still preferably 0° or larger but not larger than 60°, still preferably 0° or larger but not larger than 40°, still preferably 0° or larger but not larger than 20°, particularly preferably 0° or larger but not larger than 10° and most desirably 0° (i.e., being parallel to the substrate). The organic layer comprising the organic compound with controlled orientation as described above may be at least a part of the whole organic layer. It is preferable that the part with controlled orientation amounts to 10% or more based on the whole organic layer, still preferably 30% or more, still preferably 50% or more, still preferably 70% or more, particularly preferably 90% or more and most desirably 100%. In this construction, the shortage of the organic layer of having a short carrier diffusion length can be overcome by controlling the orientation of the organic compound in the organic layer and thus the photoelectric conversion efficiency can be elevated.

In the where the organic compound has controlled orientation, it is still preferable that the heterojunction plane (for example, a pn junction plane) is not parallel to the substrate. It is favorable that the organic compound is oriented so that the heterojunction plane is not parallel to the substrate (the electrode substrate) but as close to perpendicular as possible thereto. The angle to the substrate is preferably 10° or larger but not larger than 90°, still preferably 30° or larger but not larger than 90°, still preferably 50′ or larger but not larger than 90°, still preferably 70° or larger but not larger than 90°, particularly preferably 80° or larger but not larger than 90° and most desirably 90° (i.e., being perpendicular to the substrate). The layer of the compound with controlled heterojunction plane as described above may be a part of the whole organic layer. The part with controlled orientation preferably amounts to 10% or more based on the whole organic layer, still preferably 30% or more, still preferably 50% or more, still preferably 70% or more, particularly preferably 90% or more and most desirably 100%. In such a case, the area of the heterojunction plane in the organic layer is enlarged and, in its turn, electrons, holes, electron-hole pairs, etc. formed in the interface can be carried in an increased amount, which makes it possible to improve the photoelectric conversion efficiency. The photoelectric conversion element (a photosensitive layer) in which the orientation is controlled in both of the heterojunction plane and the π-electron plane as described above, the photoelectric conversion efficiency can be particularly improved. These states are described in detail in Japanese Patent Application No. 2004-079931.

From the viewpoint of light absorption, a larger thickness of an organic dye layer is preferred. By taking the percentage not contributing to charge separation into consideration, however, the thickness of the organic dye layer according to the invention is preferably 30 nm or more but not more than 300 nm, still preferably 50 nm or more but not more than 250 nm, and particularly preferably 80 nm or more but not more than 200 nm.

[Method of Forming Organic Layer]

The layers containing these organic compounds can be formed by a dry element-forming method or a wet element-forming method. Specific examples of the dry element-forming method include physical vapor phase epitaxy methods such as the vacuum vapor deposition method, the sputtering method, the ion plating method and the MBE method, and CVD methods such as the plasma polymerization method. Examples of the wet element-forming method include the casting method, the spin coating method, the dipping method and the LB method.

In the case of using a polymer compound as at least one of the p-type semiconductor (compound) and the n-type semiconductor (compound), it is favorable to form the layer by a wet element-forming method which can be easily carried out. When a dry element-forming method such as the vapor deposition method is employed, it is highly difficult to employ a polymer compound because of a fear of decomposition. In such a case, use may be preferably made of a corresponding oligomer as a substitute for the polymer. In the case of using a low-molecular weight compound in the invention, use is preferably made of a dry element-forming method and the vacuum vapor deposition method is particularly preferred. Fundamental parameters in the vacuum vapor deposition method include a method of heating a compound (e.g., the resistance heating method, the electron beam heating/deposition method or the like), the shape of the deposition source such as a crucible or a boat, the degree of vacuum, the deposition temperature, the substrate temperature, the deposition speed and so on. To achieve uniform deposition, it is favorable to carry out the deposition while rotating the substrate. A higher degree of vacuum is preferred. The vacuum vapor deposition is performed at a degree of vacuum of 10⁻⁴ Torr (1.33×10⁻² Pa) or lower, preferably 10⁻⁶ Torr (1.33×10⁻⁴ Pa) or lower and particularly preferably 10⁻⁸ Torr (1.33×10⁻⁶ Pa) or lower. It is preferable to carry out all of the vapor deposition steps in vacuo. Fundamentally, the subject compound should be prevented from direct contact with the external oxygen or moisture. The vacuum vapor deposition conditions as described above should be strictly controlled, since the crystalinity, amorphous properties, density and denseness of the organic layer are affected thereby. It is preferable to PI or PID control the deposition speed with the use of a thickness monitor such as a crystal oscillator or an interferometer. In the case of depositing two or more compounds at the same time, use may be preferably made of the co-deposition method, the flash deposition method or the like.

(Electrode)

The electromagnetic wave absorption/photoelectric conversion part comprising organic layers according to the invention is located between a pair of electrodes and the pair of electrodes respectively serve as a pixel electrode and a counter electrode. It is preferable that the lower layer serves as the pixel electrode.

It is preferable that the counter electrode takes out holes from a hole-transporting photoelectric conversion element or a hole-transporting layer. As a material for making the counter electrode, use may be made of a metal, an alloy, a metal oxide, an electrically conductive compound or a mixture thereof. It is preferable that the pixel electrode (including the conductive element of the invention) can take out electrons from an electron-transporting photoelectric conversion layer or an electron-transporting layer. It is selected by considering the adhesiveness to the adjacent layers such as the electron-transporting photoelectric conversion layer and the electron-transporting layer, electron affinity, ionization potential, stability and so on. Specific examples thereof include electrically conductive metal oxides such as tin oxide, zinc oxide, indium oxide and indium tin oxide (ITO), metals such as gold, silver, chromium and nickel, mixtures or laminations of these metals with electrically conductive metal oxides, inorganic conductive materials such as copper iodide and copper sulfide, organic conductive materials such as polyaniline, polythiophene and polypyrrole, silicone compounds and laminations thereof with ITO. Electrically conductive metal oxides are preferable and ITO and IZO are still preferable from the viewpoints of productivity, high conductivity, transparency and so on. The thickness may be appropriately selected depending on material. In usual, it is preferably 10 nm or more but not more than 1 μm, still preferably 30 nm or more but not more than 500 nm and still preferably 50 nm or more but not more than 300 ma.

The pixel electrode and the counter electrode may be constructed by various methods depending on materials. In the case of using ITO, for example, a layer may be formed by the electron beam method, the sputtering method, the resistance heat deposition method, the chemical reaction method (sol-gel method, etc.) or the method of coating with an indium tin oxide dispersion. In the case of using ITO, it is also possible to perform the UV-ozone treatment, the plasma treatment or the like.

In the invention, it is preferable to construct a transparent electrode element under plasma-free conditions. By constructing the transparent electrode element under plasma-free conditions, effects of plasma on the substrate can be minimized and thus favorable photoelectric conversion characteristics can be established. The term “plasma-free” as used herein means a state wherein no plasma generates in the course of forming a transparent electrode element or the distance between a plasma source and a substrate is 2 μm or longer, preferably 10 cm or longer and still preferably 20 cm or longer and, therefore, plasma is lessened until it reaches the substrate.

As examples of a device wherein no plasma generates during the element-formation of a transparent electrode element, an electron beam deposition device (an EB deposition device) and a pulse laser deposition device may be cited. Namely, use can be made of an EB deposition device or a pulse laser deposition device reported in Tomei Dodenmaku no Shintenkai, supervised by Yutaka Sawada (CMC, 1999); Tomei Dodenmaku no Shintenkai II, supervised by Yutaka Sawada (CMC, 2002); Tomei Dodenmaku no Gijutsu, Japan Society for the Promotion of Science (Ohm, 1999) and reference documents attached thereto. A method of forming a transparent electrode element by using an EB deposition device will be called the EB deposition method while a method of forming a transparent electrode element with the use of a pulse laser deposition device will be called the pulse laser deposition method hereinafter.

As examples of a device having a distance between a plasma source and a substrate of 2 cm or longer and, therefore, plasma is lessened until it reaches the substrate (hereinafter referred to as a plasma-free element forming device), a counter target sputtering device and an arc plasma deposition device may be cited. Namely, use can be made of devices reported in Tomei Dodenmaku no Shintenkai, supervised by Yutaka Sawada (CMC, 1999); Tomei Dodenmaku no Shintenkai II, supervised by Yutaka Sawada (CMC, 2002); Tomei Dodenmaku no Gijutsu, Japan Society for the Promotion of Science (Ohm, 1999) and reference documents attached thereto.

Now, the electrodes in the electromagnetic wave absorption/photoelectric conversion part of the invention will be illustrated in greater detail. The photoelectric conversion element in the organic layer, which is located between a pixel electrode element and a counter electrode element, may comprises an interelectrode material or the like. The term “pixel electrode element” means an electrode element constructed in the upper part of the substrate on which a charge storage/transfer/reading part is formed. It is usually divided for individual pixels so that a signal charge converted by the photoelectric conversion element can be read for each pixel on the charge storage/transfer/signal reading circuit substrate to give an image.

The term “counter electrode element” means an electrode element having a function of sandwiching the photoelectric conversion element together with the pixel electrode element to thereby emit a signal charge having a polarity opposite to the signal charge. Since it is unnecessary to divide the emission of the signal charge for individual pixels, pixels usually have a counter electrode element in common. Thus, it is sometimes called a common electrode element.

The photoelectric conversion element is located between the pixel electrode element and the counter electrode element. The photoelectric conversion function is established by the photoelectric conversion element, the pixel electrode element and the counter electrode element.

In the case where a single organic layer is provided on a substrate, the photoelectric conversion element lamination is composed of, for example, a substrate and a pixel electrode element (being a transparent electrode element in many case), a photoelectric conversion element and a counter electrode element (a transparent electrode element) which are provided on the substrate in this order, though the invention is not restricted thereto.

In the case where two organic layers are provided on a substrate, the photoelectric conversion element lamination is composed of, for example, a substrate and a pixel electrode element (being a transparent electrode element in many case), a photoelectric conversion element, a counter electrode element (a transparent electrode element), an interlayer insulating element, a pixel electrode element (being a transparent electrode element in many case), a photoelectric conversion element and a counter electrode element (a transparent electrode element) which are provided on the substrate in this order.

Particularly preferred examples of the material of the transparent electrode element include ITO, IZO, SnO₂, ATO (antimony-doped tin oxide), Zno, AZO (Al-doped zinc oxide), GZO (gallium-doped zinc oxide), TiO₂ and FTO (fluorine-doped tin oxide). The light transmittance of a transparent electrode element at the photoelectric conversion light absorption peak wavelength of the photoelectric conversion element contained in the photoelectric conversion device having the transparent electrode element is preferably 60% or more, still preferably 80% or more, still preferably 90% or more and still preferably 95% or more. The preferable range of the surface resistance of the transparent electrode element varies depending on, for example, whether being a pixel electrode or a counter electrode and whether the charge storage/transfer/reading part having a CCD structure or a CMOS structure. In the case of using as a counter electrode and the charge storage/transfer/reading part having a CMDS structure, the surface resistance is preferably not more than 10000 Ω/□, still preferably not more than 1000 Ω2/□. In the case of using as a counter electrode and the charge storage/transfer/reading part having a CCD structure, the surface resistance is preferably not more than 1000 Ω/□, still preferably not more than 100 Ω/□. In the case of using as a pixel electrode, the surface resistance is preferably not more than 1000000 Ω/□, still preferably not more than 100000 Ω/□.

Now, element-forming conditions for the transparent electrode element will be described. In the element-forming step of the transparent electrode element, the substrate temperature is preferably 500° C. or below, still preferably 300° C. or below, still preferably 200° C. or below and still preferably 150° C. or below. A gas may be introduced during the transparent electrode element formation. Although the gas is not fundamentally restricted in species, use may be made of Ar, He, oxygen, nitrogen or the like. It is also possible to use a mixture of these gases. In the case of using an oxide material, it is preferable to use oxygen since there frequently arises oxygen defect.

It is preferable to apply a voltage to the photoelectric conversion element of the invention to improve the photoelectric conversion efficiency. Although the application voltage may be an arbitrary one, the required voltage level varies depending on the thickness of the photoelectric conversion element. That is to say, a higher photoelectric conversion efficiency is obtained under the larger electric field applied to the photoelectric conversion element. In the case of applying a definite voltage, the electric field is elevated with a decrease in the thickness of the photoelectric conversion element. In the case of using a thin photoelectric conversion element, therefore, the applied voltage may be relatively low. The electric field to be applied to the photoelectric conversion element is preferably 10 V/m or more, still preferably 1×10³ V/m or more, still preferably 1×10⁵ V/m or more, particularly preferably 1×10⁶ V/m or more and most desirably 1×10⁷ V/m or more. Although the upper limit thereof is not particularly specified, it is undesirable to apply an excessive electric field since a current flows even in a dark place in such a case. Thus, the electric field to be applied is preferably 1×10¹²V/m or less, still preferably 1×10⁹ V/m or less.

(Inorganic Layer)

Now, an inorganic layer serving as the electromagnetic wave absorption/photoelectric conversion part will be illustrated. In this case, light passing through the upper organic layer is photoelectrically converted in the inorganic layer. As the inorganic layer, use is generally made of a pn junction or a pin junction of semiconductor compounds such as crystalline silicone, amorphous silicone and GaAs. As a laminated structure, a method disclosed by U.S. Pat. No. 5,965,875 may be employed. Namely, this method comprises forming a photo acceptance part laminated with the use of the wavelength-dependency of the absorption coefficient of silicone and performing color separation in the depth direction thereof. Since the color separation is carried out depending on the light transmission depth of silicone in this case, the spectra detected in individual acceptance parts laminated together have each a broad range. By using the organic layer as the upper layer as described above (i.e., detecting light transmitting the organic layer in the depth direction of silicone), however, the color separation can be remarkably improved (refer to JP-A-2003-332551). By providing a G layer as the organic layer, in particular, light transmitting through the organic layer is separated into B light and R light. As a result, the light may be divided merely into BR lights in the depth direction of silicone and thus the color separation is improved. In the case where the organic layer is a B layer or an R layer, the color separation can be remarkably improved too by appropriately selecting the electromagnetic wave absorption/photoelectric conversion part of silicone along the depth direction. In the case of forming two organic layers, the function as the electromagnetic wave absorption/photoelectric conversion part in silicone may be performed fundamentally in only one color and, in its turn, favorable color separation can be established.

In a preferable case, the inorganic layer has a structure wherein multiple photodiodes are laminated in the depth direction of a semiconductor substrate for individual pixels and color signals corresponding to the signal charges generating in the individual photodiodes due to light absorbed by the multiple photodiodes are read out. It is preferable that the multiple photodiodes involve at least one of a first photodiode located in the depth of absorbing B light and a second photodiode located in the depth of absorbing R light, and each of the photodiodes has a color signal reading circuit for reading a color signal corresponding to each of the signal charges. According to this constitution, color separation can be performed without resorting to a color filter. It is also possible in some cases to detect light in the negative component, which enables color image pickup with favorable color reproducibility. It is preferable in the invention that the joint part of the first photodiode is formed in a depth up to about 0.2 μm from the semiconductor substrate surface, while the joint of the second photodiode is formed in a depth up to about 2 μm from the semiconductor substrate surface.

Now, the inorganic layer will be illustrated in greater detail. Preferable examples of the inorganic layer constitution include photo acceptance devices of the photoconductive type, the p-n junction type, the shot-key junction type, the PIN junction type and the MSM (metal-semiconductor-metal) junction type and photo acceptance devices of the photo transistor type. It is preferable in the invention to employ a photo acceptance device wherein first conductive areas and second conductive areas being opposite to the first conductive areas are alternatively laminated on a single semiconductor substrate and the joint parts of the first conductive areas and the second conductive areas are formed respectively at depths appropriate mainly for the photoelectric conversion of a plural number of lights in different wavelength regions. As the single semiconductor substrate, monocrystalline silicone may be preferably employed. Thus, color separation can be performed by taking advantage of the absorption wavelength characteristics depending on the depth direction of the silicone substrate.

As the inorganic semiconductor, use can be made of InGaN-based, InAlN-based, In AlP-based or InGaAlP-based inorganic semiconductors. An InGaN-based inorganic semiconductor is prepared by appropriately altering the composition of In so as to achieve an absorption peak in the blue light wavelength region. That is to say, it is represented by InₓGa₁₋ₓN (0≦X<1). A semiconductor made of such a compound can be produced by the organic metal vapor phase epitaxy method (MOCVD method). An InAlN-based nitride semiconductor with the use of Al belonging to the same group (13) as Ga is also usable as a short wavelength light acceptor part as in the InGaN-based one. Furthermore, use can be also made of InAlP and InGaAlP lattice-matching a GaAs substrate.

The inorganic semiconductor may have an embedded structure. The term “embedded structure” means a constitution wherein both ends of a short wavelength light acceptor part are covered with a semiconductor which is different from the short wavelength light acceptor part. As the semiconductor covering both ends, it is preferable to employ a semiconductor having a band gap wavelength which is shorter than the band gap wavelength of the short wavelength light acceptor part or equals thereto.

The organic layer and the inorganic layer may be bonded in an arbitrary manner. It is preferable to provide an insulating layer between the organic layer and the inorganic layer to thereby electrically insulating them.

An npn-junction or a pnpn-junction, from the incident light side, is preferred. The pnpn-junction is still preferred, since the surface potential can be maintained at a high level by forming a p layer on the surface and thus holes and a dark current generating on the surface can be trapped, thereby lowering the dark current.

In such a photodiode, an n-type layer, a p-type layer, an n-type layer and a p-type layer are deeply formed in this order, i.e., being successively diffused from the p-type silicone substrate surface, and thus a pn-junction diode is formed in the depth direction of the silicone to give four layers (pnpn). Incident light with a longer wavelength entering from the diode surface side the more deeply transmits and the incident wavelength and the attenuation coefficient are inherent to silicone. Thus, the diode is designed so that the pn junction face covers the wavelength region of visible light. Similarly, an n-type layer, a p-type layer and an n-type layer are formed in this order to give a junction diode having three layers (npn). A light signal is taken out from the n-type layer, while the p-type layer is ground connected.

By forming a drawing electrode in each area and applying a definite reset potential thereto, each area becomes depletion and the capacity in each junction part is highly lessened. Thus, the capacity generating in the junction face can be highly lessened.

(Auxiliary Layer)

It is preferable in the invention to provide an ultraviolet absorption layer and/or an infrared absorption layer as the uppermost layer of the electromagnetic wave absorption/photoelectric conversion part. The ultraviolet absorption layer can absorb or reflect light having wavelength of at least 400 nm or less and it preferably has an absorption index in a wavelength region of 400 nm or less of 50% or more. The infrared absorption layer can absorb or reflect light having wavelength of at least 700 nm or more and it preferably has an absorption index in a wavelength region of 700=m or more of 50% or more.

These ultraviolet absorption layer and infrared absorption layer can be formed by publicly known methods. For example, there has been known a method which comprises forming a mordant layer made of a hydrophilic polymer such as gelatin, casein, glue or polyvinyl alcohol on the substrate and adding a dye having a desired absorption wavelength to the mordant layer or dyeing the mordant layer to form a color layer. Another known method comprises using a colored resin wherein a specific coloring matter is dispersed in a transparent resin. Moreover, use may be made of a colored resin element comprising a mixture of a polyamino resin with a coloring matter, as reported by JP-A-58-46325, JP-A-60-78401, JP-A-60-184202, JP-A-60-184203, JP-A-60-184204, JP-A-60-184205 and so on. It is also possible to use a coloring agent comprising a photosensitive polyimide resin.

Furthermore, it is possible to disperse a coloring matter in an aromatic polyamide resin which has a photosensitive group in its molecule and can provide a hardened element at 200° C. or below, as reported by JP-B-7-113685. Also, use can be made of a dispersion colored resin in an amount as specified in JP-B-7-69486.

In the invention, it is preferable to use a dielectric multilayer element. The advantage of using a dielectric multilayer element resides in that it has a sharp wavelength-dependency of light transmission.

It is preferable that individual electromagnetic wave absorption/photoelectric conversion parts are separated by insulating layers. These insulating layers can be formed by using transparent insulating materials such as glass, polyethylene, polyethylene terephthalate, polyether sulfone or polypropylene. Also, use may be preferably made of silicon nitride, silicon oxide and the like. A silicon nitride element formed by the plasma CVD method is preferably used because of being highly dense and highly transparent.

To prevent direct contact with oxygen or moisture, it is also possible to form a protective layer or a blocking layer. Examples of the protective layer include a diamond element, elements made of inorganic materials such as metal oxides and metal nitrides, elements made of polymers such as fluororesins, poly(para-xylene), polyethylene, silicone resins and polystyrene resins, and photosetting resins. It is also possible package the device per se by covering it with glass, a gas non-permeable plastic, a metal, etc. In this case, it is also possible to enclose a substance having a high water absorption property in the package.

Furthermore, it is preferable to employ an embodiment wherein a microlens array is formed in the upper part of the photo acceptance device so as to improve the light collection efficiency.

(Charge Storage/Transfer/Reading Part)

Concerning the charge storage/transfer/reading part, reference may be made to JP-A-58-103166, JP-A-58-103165, JP-A-2003-332551 and so on. Namely, use may be appropriately made of a constitution wherein MOS transistors are formed for individual pixels on a semiconductor substrate or a constitution having CCD as a device. In the case of a photoelectric conversion device with the use of MOS transistors, for example, electric charge arises in a photoconductive element due to incident light transmitting through electrodes. By applying a voltage to the electrodes, an electric field is formed between the electrodes and thus the charge migrates across the photoconductive element toward the electrodes. Then the charge enters into a charge storage part in the MOS transistor and stored therein. The charge stored in the charge storage part transfers to a charge-reading part by switching the MOS transistor and then output as an electric signal. Owing to this mechanism, a full color image signals are input in the solid-state image pickup device having a signal processing part.

It is also possible that a definite amount of bias charge is injected into a storage diode (a refresh mode) and, after storing a definite charge (a photoelectric conversion mode), the signal charge is read out. It is possible to use a photo acceptance device per se as a storage diode or to separately provide a storage diode.

Next, signal reading will be illustrated in greater detail. Signals can be read by using a conventional color reading circuit. A signal charge or a signal current phtoelectrically converted in the photo acceptance part is stored in the photo acceptance part per se or a capacitor provided separately. The thus stored charge is read simultaneously with the selection of pixel position by the means of MOS image pickup device with the use of the X-Y address system (a so-called CMOS sensor). As another reading method, an address selection system which comprises successively selecting pixels one by one with a multi prexar switch and a digital shift switch and reading as a signal voltage (or charge) along a common output curve may be cited. There is an image pickup device with the use of a two-dimensionally arrayed X-Y address operation which is known as a CMSO sensor. In this device, a switch attached to the X-Y intersection is connected to a perpendicular shift resistor. When the switch is turned on by the voltage from the perpendicular scanning shift resistor, signals read from pixels in the same line are read along the output curve in the ray direction. These signals are read one by one from the output end through a switching mechanism which is driven by a horizontal scanning shift resistor.

To read output signals, use can be made of a floating diffusion detector or a floating gate detector. Moreover, S/N can be improved by providing pixels with a signal amplification circuit or using the correlated double sampling method.

Signals can be processed by using gamma correlation with the use of an ADC circuit, digitalization with the use of an AD converter, the luminance signal processing method or the color signal processing method. Examples of the color signal processing method include white balance processing, color separation processing, color matrix processing and so on. In order to use as NTSC signals, the RGB signals can be converted into YIQ signals.

In the charge transfer/reading part, the charge migration rate should be 100 cm²/volt see or higher. Such a migration rate can be established by selecting an appropriate semiconductor material belonging to the group IV, III-V or II-VI. Among all, it is preferable to employ silicone semiconductors (also called Si semiconductors), since fine processing techniques have advanced in this field and they are available at low cost. There have been proposed a large number of charge transfer/charge reading systems and any of these systems is usable. A CMSO-type or CCD-type device system is particularly preferred. In the invention, the CMSO-type system is preferred in various points including high-speed reading, pixel integration, partial reading and power consumption.

(Connection)

Multiple parts for connecting the electromagnetic wave absorption/photoelectric conversion part to the charge storage/transfer/reading part may be made of any metal. It is preferable to use a metal selected from among copper, aluminum, silver, gold, chromium and tungsten and copper is particularly preferable therefor. Contact parts should be respectively provided between individual electromagnetic wave absorption/photoelectric conversion parts and individual charge storage/transfer/reading parts. In the case of using a laminated structure comprising blue, green and red light photosensitive units, it is necessary to connect a fetch electrode for blue light to a charge transfer/reading part, to connect a fetch electrode for green light to a charge transfer/reading part and to connect a fetch electrode for red light to a charge transfer/reading part respectively.

(Process)

The laminated photoelectric conversion device according to the invention can be fabricated in accordance with a so-called micro fabrication process employed in fabricating publicly known integrated circuits and so on. In this process, the following procedures are repeated fundamentally: pattern exposure with the use of active rays or electron beams (i, g bright-line of mercury, eximer laser, X-ray, electron beams, etc.); pattern formation by development and/or burning; provision of device-forming materials (coating, vapor deposition, sputtering, cv, etc.); and removal of the materials from non-pattern areas (heating, dissolution, etc.).

(Use)

Concerning the chip size, the device may have the brownie size, the 135 size, the APS size, the 1/1.8 size or a smaller size. In the laminated photoelectric conversion device of the invention, the pixel size is expressed in diameter of a circle corresponding to the maximum area of multiple electromagnetic wave absorption/photoelectric conversion parts. Although any pixel size may be used, a pixel size of 2 to 20 μm is preferable, still preferably 2 to 10 μm and particularly preferably 3 to 8 μm.

In the case where the pixel size exceeds 20 μm, the resolution is lowered. In the case where the pixel size is less than 2 μm, the resolution is also lowered due to radio interference among sizes.

The photoelectric conversion device of the invention is usable in digital still cameras. It is also preferably usable in TV cameras. In addition thereto, the photoelectric conversion device of the invention is usable in digital video cameras, monitor cameras (to be used in, for example, office buildings, parking areas, financial institutions, automatic loan-application machines, shopping centers, convenience stores, outlet malls, department stores, pinball parlors, karaoke boxes, game centers and hospitals), other various sensors (entrance monitors, identification sensors, sensors for factory automation, robots for household use, robots for industrial use and pipe inspection systems), medical sensors (endoscopes and fundus cameras), TV conference systems, TV telephones, camera-equipped cell phones, safe driving systems for automobiles (back guide monitors, collision-estimating systems and lane-keeping systems), sensors for TV games and so on.

Among all, the photoelectric conversion device of the invention is appropriately usable in TV cameras. This is because the photoelectric conversion device of the invention requires no optical system for color separation and thus contributes to the reduction in size and weight of TV cameras. Moreover, it has a high sensitivity and a high resolution and, therefore, is particularly preferable in TV cameras for high-definition broadcast. The TV cameras for high-definition broadcast as used herein include cameras for digital high-definition broadcast.

The photoelectric conversion device of the invention requires no optical low pass filter, which makes it further preferable from the viewpoint of achieving an elevated sensitivity and improved resolution.

Furthermore, the thickness of the photoelectric conversion device according to the invention can be lessened and no optical system for color separation is required therein. Thus, it can provide a single camera which meets various photography-related heeds. Namely, scenes wherein different sensitivities are needed, e.g., “environments with a change in brightness, e.g., daytime and night”, “a still subject and a moving subject” and so on, and scenes wherein different spectral sensitivities or color reproductions are needed can be taken with the use of a single camera merely replacing the photoelectric conversion devices of the invention. Therefore, it becomes unnecessary to carry a plural number of cameras, which lessen the load on a photographer. To replace the photoelectric conversion devices, the above-described photoelectric conversion device is prepared together with spare photoelectric conversion devices for, e.g., infrared light photographing, monochromric photographing, dynamic range replacement and so on.

The TV camera according to the invention can be fabricated by reference to Terebi Kamera no Sekkei Gijutsu, ed. by The Institute of Image Information and Television Engineers (Aug. 20, 1999, Corona, ISBN 4-339-00714-5) chap. 2 and replacing, for example, the optical system for color separation and the image pickup device in FIG. 2.1 (Fundamental Constitution of TV Camera) therein by the photoelectric conversion device of the invention.

The laminated photo acceptance devices as described above may be used as an image pickup device by aligning. Alternatively, a single device can be used as a photo sensor or a color photo acceptance device in biosensors and chemical sensors.

(Preferable Photoelectric Conversion Device According to the Invention)

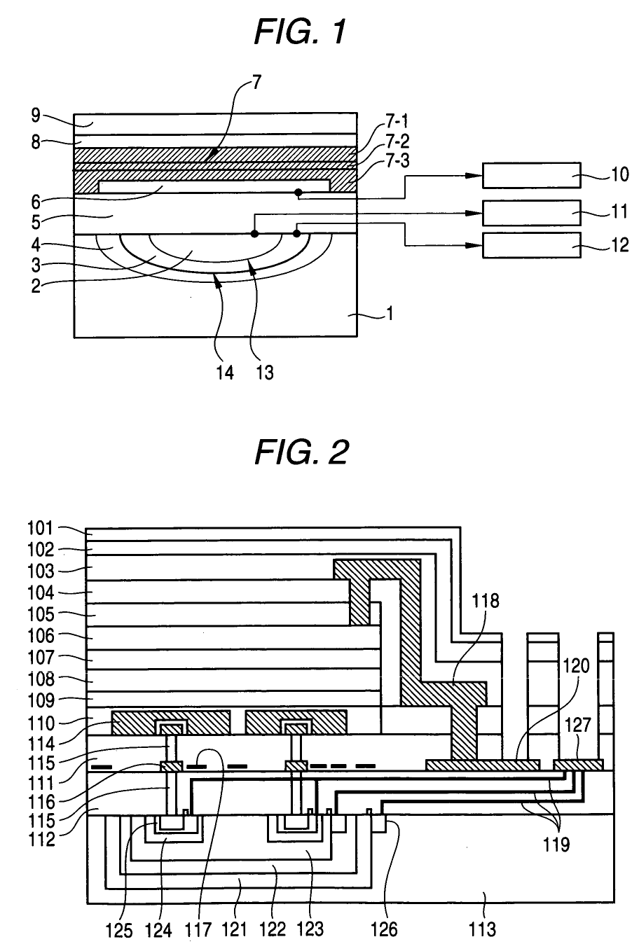

Next, a preferable photoelectric conversion device of the invention will be illustrated by referring to FIG. 1. In FIG. 1, 113 is a monocrystalline silicone base which also serves as electromagnetic wave absorption/photoelectric conversion parts for B light and R light and a charge storage/transfer/reading part for the charge generated by photoelectric conversion. A p-type silicone substrate is usually employed therefor. 121, 122 and 123 respectively show an n layer, a player and another n layer formed in the silicone base. The n layer 121 is an R light signal charge storage part in which R light signal charge photoelectrically converted by the pn junction is stored. The thus stored charge is connected to a signal reading pad 127 by a metal wiring 119 via a transistor 126. The n layer 123 is a B light signal charge storage part in which B light signal charge photoelectrically converted by the pn junction is stored. The thus stored charge is connected to the signal reading pad 127 by the metal wiring 119 via a transistor similar to the transistor 126. Although the p layer, n layers, transistors, metal wirings, etc. are schematically indicated therein, each member has an appropriately selected structure, etc. as discussed above. Since B light and R light are fractionated depending on silicone base depth, it is important to appropriately select the depth of the pn junction etc. from the silicone base, the dope concentration and so on. A layer 112 contains a metal wiring and comprises silicon oxide, silicone nitride, etc. as the main component. A less thickness of the layer 112 is preferred. Namely, its thickness is 5 μm or less, preferably 3 μm or less and still preferably 2 μm or less. Similarly, a layer 111 comprises silicon oxide, silicone nitride, etc. as the main component. Between the layers 111 and 112, a plug for transferring G light signal charge to the silicone base is provided. The plug is connected by a pad 116 between the layers 111 and 112. As the plug, use is preferably made of one comprising tungsten as the main component. As the pad, use is preferably made of one comprising aluminum as the main component. It is preferred that a barrier layer is formed including the metal wiring as described above. The G light signal charge transferred through the plug 115 is stored in the n layer 125 in the silicone base. The n layer 125 is separated by the p layer 124. The stored charge is connected to the signal reading pad 127 by the metal wiring 119 via a transistor similar to the transistor 126. Since the photoelectric conversion by the pn junction of 124 and 125 brings about noises, a photo blocking element 117 is provided in the layer 111. As the photo blocking layer, use is usually made of one comprising tungsten, aluminum or the like as the main component. A less thickness of the layer 112 is preferred. Namely, its thickness is 3 μm or less, preferably 2 μm or less and still preferably 1 μm or less. It is preferable to provide a signal reading pad 127 for each of B, G and R signals. The above described process can be carried out by a publicly known process, i.e., the so-called CMOS process.

The electromagnetic wave absorption/photoelectric conversion parts of G light are represented by 105, 106, 107, 108, 109, 110 and 114. 105 and 114 stand for transparent electrodes which correspond respectively to a counter electrode and a pixel electrode. Although the pixel electrode 114 is a transparent electrode, it is frequently needed to provide a part made of aluminum, molybdenum, etc. to the connection area so as to achieve favorable electrical connection to a via plug 115. A bias is loaded between these transparent electrodes via the wirings from a connection electrode 118 and the counter electrode pad 120. In a preferred structure, positive bias is loaded on the pixel electrode 114 to the counter electrode 5 and thus electrons are stored in 25. In this case, 106 serves as an electron blocking layer, 107 serves as a G dye (p) layer, 108 serves as a G dye (n) layer, 109 serves as a layer for preventing uneven crystallization and 110 serves as a hole blocking layer, thus showing a typical layer structure of the organic layers. The total thickness of the organic layers 106, 107, 108, 109 and 110 is preferably 0.5 μm or less, still preferably 0.3 μm or less and particularly preferably 0.2 μm or less. The thicknesses of the transparent counter electrode 105 and the transparent pixel electrode 114 are preferably 0.2 μm or less. 103 and 104 are protective elements comprising silicon nitride, etc. as the main component. Owing to these protective elements, the process for fabricating the layers including the organic layers becomes easy. These layers particularly contribute to the relief in damages on the organic layers in the course of the resist pattern formation, etching, etc. in constructing the connection electrodes such as 118. It is also possible to employ a fabrication process with the use of a mask to omit the steps of forming a resist pattern and etching. The thicknesses of the protective elements 103 and 104 are preferably 0.5 μm or less, so long as the above-described requirements are fulfilled.

103 stands for a protective element of the connection electrode 118. 2 stands for an infrared-cutting dielectric multilayer element. 101 stands for an antireflective element. It is preferable that the total thickness of the layers 101, 102 and 103 is 1 μm or less.

In the photoelectric conversion device shown in FIG. 1 as described above, four G pixels are employed per B pixel and R pixel. One G pixel may be used per B pixel and R pixel. Three G pixels may be used per B pixel and R pixel. Two G pixels may be used per B pixel and R pixel. Moreover, other arbitrary combinations may be employed. Although a preferred embodiment of the invention has been described above, the invention is not restricted thereto.

### EXAMPLES

Next, examples of the invention will be provided. However, it is needless to say that the invention is not restricted thereto.

### Example 1

After forming an ITO electrode (about 100 nm) on a glass substrate, a bathocuproine (a hole blocking agent) element having a thickness of about 180 nm (determined based on the monitor value of a crystal oscillator) was formed by the resistance heating vacuum vapor deposition method (target substrate temperature: room temperature, degree of vacuum: 2×10⁻⁴ Pa). By using the same vacuum vapor deposition method, an aluminum quinoline (Alq₃) (an agent for preventing uneven crystallization) element having a thickness of about 30 n=was formed at 270° C. and then a 2,9-dimethylquinacridone (a G dye) element having a thickness of about 180 nm was formed at 370° C. Moreover, an aluminum element having a thickness of 100 nm was formed thereon as the uppermost layer, thereby fabricating a G-sensitive photoelectric device.

At 25° C., an electric field (intensity: 1×10⁶ V/cm) was applied as a bias voltage between both electrodes. By irradiating with light (580 nm) from the ITO electrode side, the stationary current was measured. The same device was placed in a dark room and a bias voltage of the same electrical field intensity was applied. Then the stationary current was measured.

### Example 2

On an aluminum pixel electrode (pixel size: 10 μm) formed on a silicone substrate, a bathocuproine element having a thickness of about 180 nm was formed at 220° C. by the same method as in Example (1). Subsequently, an aluminum quinoline element having a thickness of about 30=m was formed at 270° C. and then a 2,9-dimethylquinacridone element having a thickness of about 180 nm was formed at 370° C. Moreover, an MgAg element having a thickness of 10 nm was formed thereon as the uppermost layer, thereby fabricating a G-sensitive photoelectric device. At 25° C., an electric field (intensity: 1×10⁶ V/cm) was applied as a bias voltage between both electrodes. By irradiating with light (580 nm) from the MgAg electrode side, the stationary current was measured. The same device was placed in a dark room and a bias voltage of the same electrical field intensity was applied. Then the stationary current was measured. Moreover, white spots in an image output in the dark room were observed.

FIG. 1 and FIG. 2 show preferred embodiments of photoelectric conversion devices having the photoelectric conversion elements as described respectively in Examples 1 and 2 each comprising a hole blocking layer, a layer for preventing uneven crystallization and a G photoelectric conversion layer containing a G dye.

### Comparative Example (1)

A device was fabricated as in Example (1) but forming no aluminum quinoline layer. Then a bias voltage of the same electrical field intensity was applied and the stationary current was measured.

### Comparative Example (2)

A device was fabricated as in Example (2) but forming no aluminum quinoline layer. Then a bias voltage of the same electrical field intensity was applied and the stationary current was measured. Moreover, white spots in an image output in the dark room were observed.

TABLE 1

| | | deposition |
|---|---|---|
| | Crystallization | temp. |
| Compound | temp. (° C.) | (° C.) |
| 2,9-Dimethylquinacridone | 20 | 370 |
| Aluminum quinoline (Alq₃) | 120 | 270 |
| Bathocuproine | 60 | 220 |

TABLE 2

| | Photo current/ | | |
|---|---|---|---|
| | dark current | external quantum | |
| | rate | efficiency (%) | White spot |
| Ex. (1) | 1000 | 20 | — |
| C. Ex. (1) | 5 | 20 | — |
| Ex. (2) | 900 | 18 | No spot was formed. |
| C. Ex. (2) | 4 | 18 | A large number of |
| | | | spots were formed all |
| | | | over the face. |

Based on these results, it was assumed that bathocuproine underwent crystallization in the course of the depositing 2,9-dimethylquinacridone at a high temperature directly thereon and thus the crystallized parts suffered from lowering in the blocking ability, thereby forming white spots (i.e., a phenomenon similar to light-leakage).

According to the invention, it is possible to effectively establish the inherent functions of a photoelectric conversion device with the use of an organic compound, preferably a multilayer color image pickup (light-receiving) device or a color light-emitting device, by preventing troubles occurring in the production process thereof.

This application is based on Japanese Patent application JP 2005-50944, filed Feb. 25, 2005, the entire content of which is hereby incorporated by reference, the same as if set forth at length.

What is claimed is:

1. A photoelectric conversion element comprising:
a layer containing an organic compound having a crystallization temperature of from 30 to 200° C.;
an intermediate layer containing a compound having a crystallization temperature higher by from 20 to 100° C. than the crystallization temperature of the organic compound and a deposition temperature higher by from 30 to 200° C. than a deposition temperature of the organic compound; and
a functional layer containing a compound having a crystallization temperature lower by from 20 to 100° C. than the crystallization temperature of the organic compound and a deposition temperature higher by from 50 to 300° C. than a deposition temperature of the organic compound,
provided in this order.

2. The photoelectric conversion element as claimed in claim 1, wherein the layer containing the organic compound is a charge blocking layer.

3. The photoelectric conversion element as claimed in claim 1, wherein the functional layer is a photoelectrical conversion layer.

4. The photoelectric conversion element as claimed in claim 1, wherein the compound contained in the intermediate layer has a work function falling within a reasonable scope in an energy diagrams of compounds adjacent thereto.

5. The photoelectric conversion element as claimed in claim 1, wherein the compound contained in the intermediate layer is aluminum quinoline.

6. The photoelectric conversion element as claimed in claim 1, wherein the compound contained in the intermediate layer has a crystallization temperature higher by from 30 to 80° C. than the crystallization temperature of the organic compound and a deposition temperature higher by from 40 to 180° C. than a deposition temperature of the organic compound.

7. The photoelectric conversion element as claimed in claim 1, wherein the intermediate layer has a thickness of 1 μm or less.

8. The photoelectric conversion element as claimed in claim 1, wherein the intermediate layer has a thickness of 500 nm or less.

9. A photoelectric conversion device comprising the photoelectric conversion element as claimed in claim 1.

10. A method for producing a photoelectric conversion element comprising:
forming a layer containing an organic compound having a crystallization temperature of from 30 to 200° C. by a vacuum vapor deposition method at 10⁻⁶ Pa or below;
forming a layer containing a compound having a crystallization temperature higher by from 20 to 100° C. than the crystallization temperature of the organic compound and a deposition temperature higher by from 30 to 200° C. than a deposition temperature of the organic compound by a vacuum vapor deposition method at 10⁻⁶ Pa or below; and
forming a functional layer containing a compound having a crystallization temperature lower by from 20 to 100° C. than the crystallization temperature of the organic compound and a deposition temperature higher by from 50 to 300° C. than a deposition temperature of the organic compound by a vacuum vapor deposition method at 10⁻⁶ Pa or below,
in this order.
